(19) United States
(12) Patent Application Publication
(10) Pub. No.: US 2026/0293043 A1
(43) Pub. Date: Sep. 24, 2026

(54) EXTERNAL HEAT DISSIPATION MODULE, SERVER ASSEMBLY, SERVER SYSTEM

(71) Applicant: PEGATRON CORPORATION, TAIPEI CITY (TW)

(72) Inventors: Hsiang-Yu Huang, Taipei City (TW); Fu-Jen Yang, Taipei City (TW); Wei-Cheng Liu, Taipei City (TW)

(73) Assignee: PEGATRON CORPORATION, TAIPEI CITY (TW)

(21) Appl. No.: 19/537,112

(22) Filed: Feb. 11, 2026

(30) Foreign Application Priority Data
Mar. 24, 2025 (TW) 114202892

(51) Int. Cl. H05K 7/20; H05K 7/14

(52) U.S. Cl. CPC H05K 7/20272; H05K 7/1489; H05K 7/20409; H05K 7/20736; H05K 7/20781

(57) ABSTRACT

An external heat dissipation module is connected to a server and includes a chassis, a liquid inlet connector, a liquid outlet connector, a liquid cooling radiator, and first and second pipelines. The liquid inlet connector and the liquid outlet connector are exposed from the chassis and are arranged at a same side of the chassis. The liquid cooling radiator and the first and second pipelines are located inside the chassis. The first pipeline is connected to the liquid inlet connector and the liquid cooling radiator. The second pipeline is connected to the liquid outlet connector and the liquid cooling radiator. Liquid in the server flows from the liquid inlet connector to the liquid cooling radiator through the first pipeline, and after being cooled by the liquid cooling radiator, flowing back to the server from the liquid cooling radiator to the liquid outlet connector through the second pipeline.

### CROSS-REFERENCE TO RELATED APPLICATION

This application claims the priority benefit of Taiwan application serial no. 114202892, filed on Mar. 24, 2025. The entirety of the above-mentioned patent application is hereby incorporated by reference herein and made a part of this specification.

### BACKGROUND

### Technical Field

The disclosure relates to a heat dissipation module, and particularly relates to an external heat dissipation module externally connected to a server.

### Description of Related Art

With the advancement of technology, the computing load of servers has increased, generating more and more heat. If a heat dissipation module is installed inside the server, due to the limited space inside the server, the heat dissipation module has a small volume, resulting in a smaller heat dissipation wattage. Currently, there is a water cooling system installed on the back of cabinet to dissipate heat for servers on the cabinet. However, the entire water cooling system has a uniform air volume and coolant flow rate, and cannot be adjusted according to the number and installation positions of servers on the cabinet.

### SUMMARY

The disclosure provides an external heat dissipation module, which may be directly externally connected to a server, and may independently dissipate heat for the connected server.

This case provides a server assembly and a server system, which have the aforementioned external heat dissipation module, and may have better heat dissipation flexibility.

An external heat dissipation module of the disclosure is adapted for being connected to a server and includes a chassis, a liquid inlet connector, a liquid outlet connector, a liquid cooling radiator, a first pipeline, and a second pipeline. The liquid inlet connector and the liquid outlet connector are exposed from the chassis. The liquid inlet connector and the liquid outlet connector are disposed on the same side of the chassis. The liquid cooling radiator is located inside the chassis. The first pipeline is located in the chassis and is connected to the liquid inlet connector and the liquid cooling radiator. The second pipeline is located in the chassis and connected to the liquid outlet connector and the liquid cooling radiator. Liquid in the server is adapted for flowing from the liquid inlet connector to the liquid cooling radiator through the first pipeline, and after being cooled by the liquid cooling radiator, flowing back to the server from the liquid cooling radiator to the liquid outlet connector through the second pipeline.

The server assembly of the disclosure includes a server and the aforementioned external heat dissipation module. The server includes a first fluid connector and a second fluid connector located on the same side. The external heat dissipation module may be pluggably assembled to the server 40. In response to the external heat dissipation module being assembled to the server, the liquid inlet connector is docked with the first fluid connector, the liquid outlet connector is docked with the second fluid connector, and the server and the external heat dissipation module are located at a same plane.

The server system of the disclosure includes a cabinet, a server, and the aforementioned external heat dissipation module. The server is detachably disposed in the cabinet and includes a first fluid connector and a second fluid connector located on the same side. The external heat dissipation module is detachably disposed in the cabinet, and is detachably assembled to the server. In response to the external heat dissipation module being assembled to the server, the liquid inlet connector is docked with the first fluid connector, the liquid outlet connector is docked with the second fluid connector, and the server and the external heat dissipation module are located at a same plane.

Based on the above, the liquid inlet connector and the liquid outlet connector of the external heat dissipation module of the disclosure are exposed on the same side of the chassis. In response to the external heat dissipation module being docked with the server, the liquid of the server may flow from the first fluid connector through the liquid inlet connector and the first pipeline of the external heat dissipation module to the liquid cooling radiator, and after being cooled by the liquid cooling radiator, flows from the second pipeline and the liquid outlet connector to the second fluid connector of the server, and returns to the server. That is, the external heat dissipation module of the disclosure may be directly externally connected to the server to dissipate heat for the server, improving heat dissipation efficiency and avoiding resource waste, and is not limited by the internal dimensions of the server.

### BRIEF DESCRIPTION OF THE DRAWINGS

FIGS. 1 and 2 are schematic diagrams of different viewing angles of an external heat dissipation module according to an embodiment of the disclosure.

FIG. 3 is an exploded view of FIG. 1.

FIG. 4 is a top view of FIG. 1 with a cover body hidden.

FIGS. 5 and 6 are schematic diagrams of different viewing angles of a server system according to an embodiment of the disclosure.

FIG. 7 is a partially enlarged top view of FIG. 5.

### DESCRIPTION OF THE EMBODIMENTS

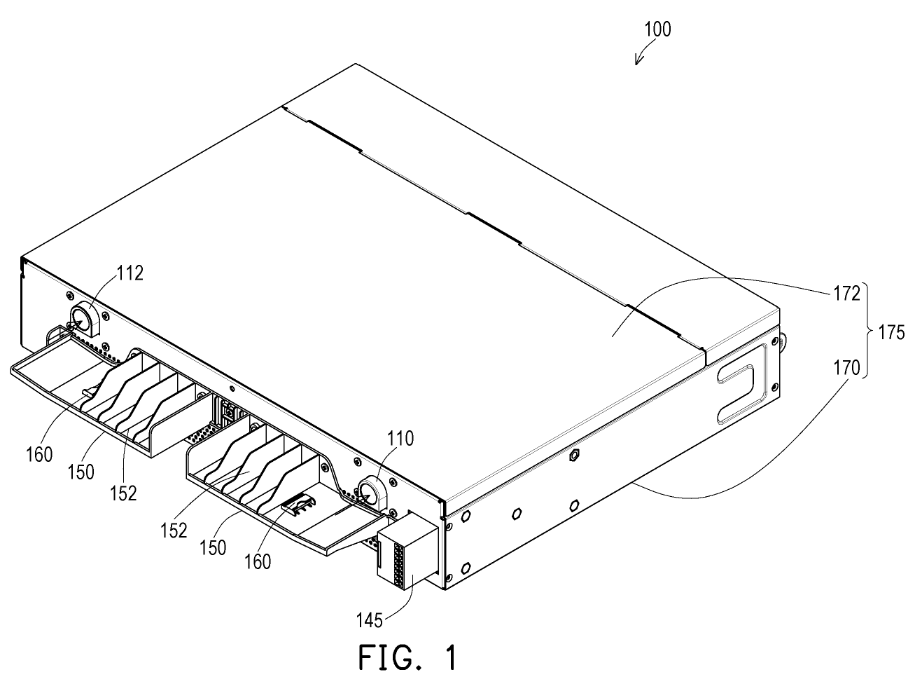

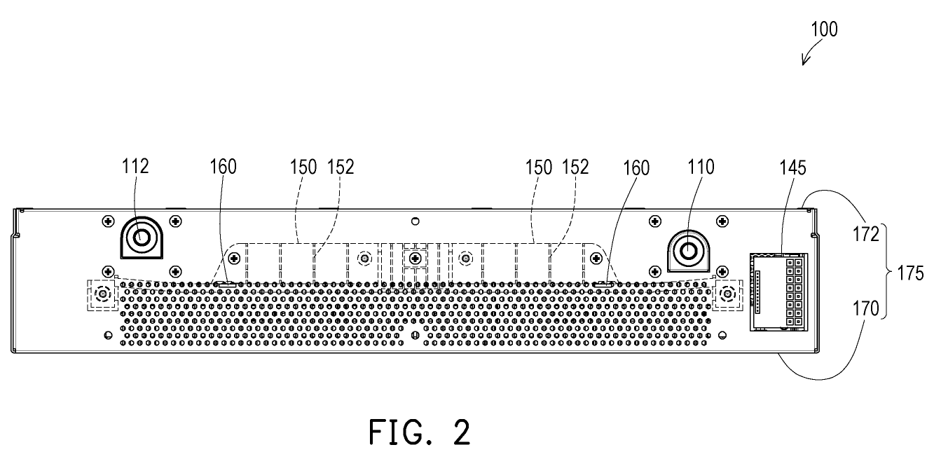

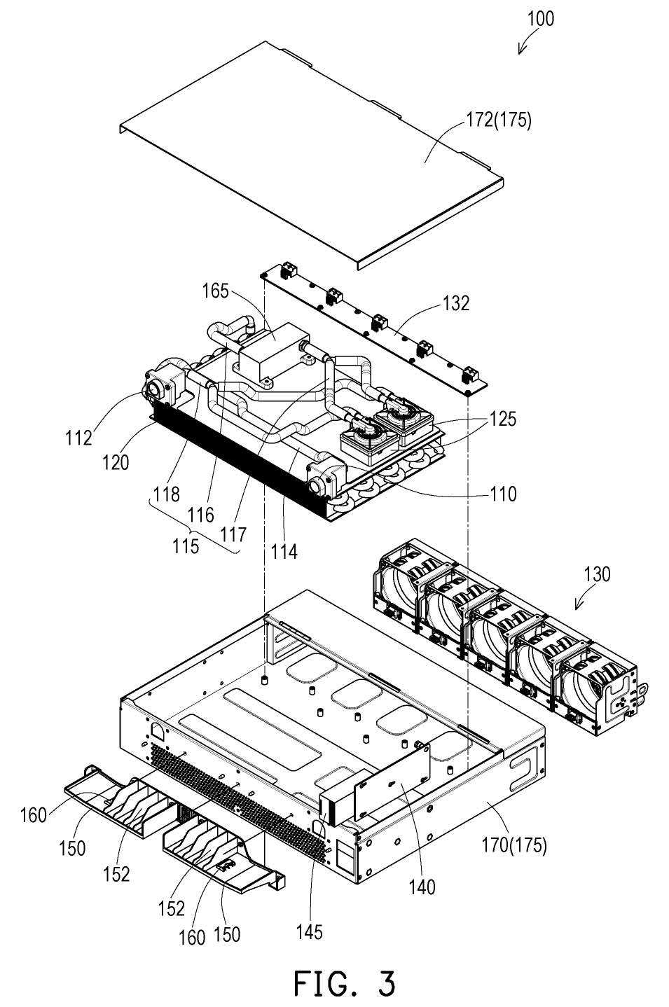

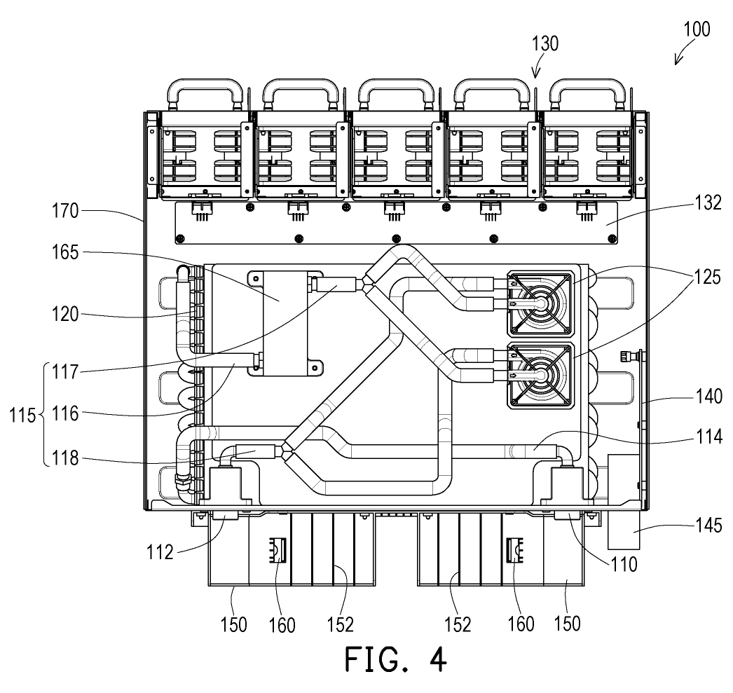

FIGS. 1 and 2 are schematic diagrams of different viewing angles of an external heat dissipation module according to an embodiment of the disclosure. FIG. 3 is an exploded view of FIG. 1. FIG. 4 is a top view of FIG. 1 with a cover body hidden.

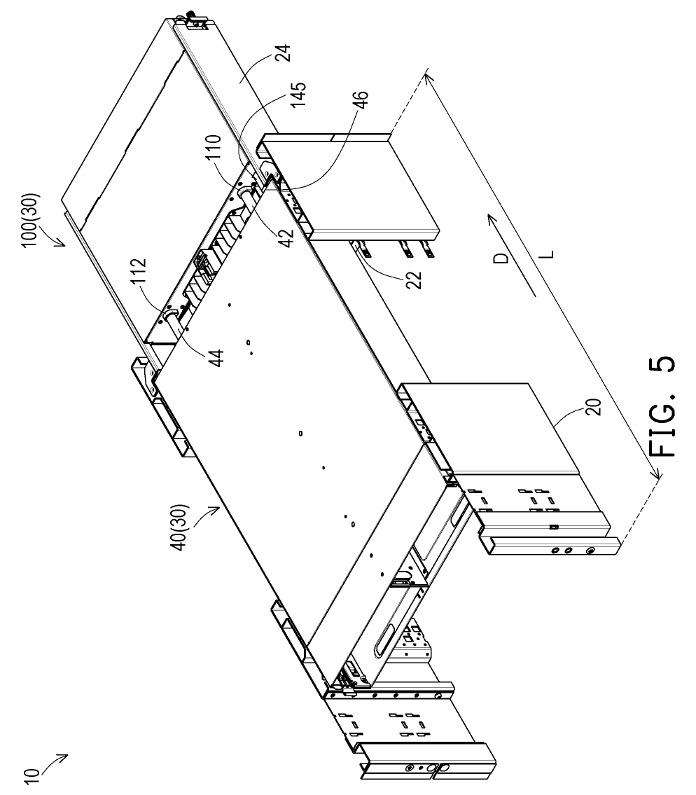

Referring to FIGS. 1 to 4, the external heat dissipation module 100 of this embodiment is adapted to be connected to a server 40 (FIG. 5) to dissipate heat from the server 40. Since the external heat dissipation module 100 is externally connected to the server 40, the external heat dissipation module 100 may not be limited by the internal dimensions of the server 40 and may have sufficient dimensions to provide good heat dissipation capability. In addition, in the case where the external heat dissipation module 100 is applied to a cabinet 20 (FIG. 5), one server 40 in the cabinet 20 may be paired with one external heat dissipation module 100. In the case where the servers 40 are not fully assembled in the cabinet 20, it is not necessary to activate the cooling system installed on the back of the cabinet 20 as in the conventional art, thereby avoiding resource waste. Furthermore, since the external heat dissipation module 100 is designed to dissipate heat for the connected server 40, the heat dissipation amount may be adjusted according to the heat generation state of the server 40, thereby achieving good heat dissipation efficiency. The external heat dissipation module 100 will be described in detail below.

As shown in FIGS. 3 and 4, in this embodiment, the external heat dissipation module 100 includes a chassis 175, a liquid inlet connector 110, a liquid outlet connector 112, a liquid cooling radiator 120, a first pipeline 114, and a second pipeline 115.

The chassis 175 includes a housing 170 and a cover body 172. The liquid inlet connector 110 and the liquid outlet connector 112 are exposed from the chassis 175. The liquid inlet connector 110 and the liquid outlet connector 112 are exposed on the same side of the chassis 175. The liquid cooling radiator 120 is located inside the chassis 175. The first pipeline 114 is located in the chassis 175 and is connected to the liquid inlet connector 110 and the liquid cooling radiator 120. The second pipeline 115 is located in the chassis 175 and is connected to the liquid outlet connector 112 and the liquid cooling radiator 120.

As shown in FIGS. 3 and 4, the external heat dissipation module 100 further includes a liquid tank 165 and at least one pump 125. The liquid tank 165 is located in the chassis 175, and the liquid tank 165 is configured to store the liquid cooled by the liquid cooling radiator 120. The at least one pump 125 is located in the chassis 175 and is connected to the liquid tank 165, and the pump 125 is configured to drive the flow of the cooled liquid. That is, the pump 125 is provided to regulate the flow rate and flow volume of the liquid.

In this embodiment, the second pipeline 115 further includes a first sub-pipe 116, a second sub-pipe 117, and a third sub-pipe 118. The first sub-pipe 116 connects the liquid cooling radiator 120 and the liquid tank 165. The second sub-pipe 117 connects the liquid tank 165 and the pump 125. The third sub-pipe 118 connects the pump 125 and the liquid outlet connector 112.

In this embodiment, the at least one pump 125 includes two pumps 125 connected in parallel, and the two pumps 125 are connected to the second sub-pipe 117 and the third sub-pipe 118 of the second pipeline 115. The two pumps 125 may operate alternately, or one of the pumps 125 may serve as a backup. Certainly, the number of pumps 125 is not limited thereto. The external heat dissipation module 100 further includes a fan assembly 130, a main circuit board 140, and a module electrical connector 145. The fan assembly 130 is located in the chassis 175 and blows air toward the liquid cooling radiator 120 to cool the liquid. The main circuit board 140 is located in the chassis 175 and is electrically connected to the fan assembly 130 and the pump 125. In this embodiment, the fan assembly 130 is electrically connected to the main circuit board through a fan circuit board 132.

The module electrical connector 145 is electrically connected to the main circuit board 140, and the module electrical connector 145 is configured to obtain power from the server 40 and may also transmit signals with the server 40. The module electrical connector 145 is exposed from the chassis 175 and is electrically connected to the main circuit board 140. The module electrical connector 145, the liquid inlet connector 110, and the liquid outlet connector 112 are exposed on the same side of the external heat dissipation module 100 for docking with the server 40.

As shown in FIGS. 1 and 2, the external heat dissipation module 100 may optionally include a water receiving tray 150 (shown in dashed lines in FIG. 2), located below the liquid inlet connector 110 and the liquid outlet connector 112. In this embodiment, the water receiving tray 150 is arc-shaped and two sides of the water receiving tray 150 are higher than the center. Such a design may allow leaked coolant to concentrate at a position near the center of the water receiving tray 150, preventing it from easily dripping from the edges on two sides. In addition, in this embodiment, the water receiving tray 150 may optionally include a plurality of upright structural reinforcing ribs 152, which may increase the structural strength of the water receiving tray 150.

In addition, the external heat dissipation module 100 further includes a liquid leakage sensor 160, disposed on the water receiving tray 150 and electrically connected to the main circuit board 140. The liquid leakage sensor 160 is configured to sense whether liquid has leaked. In response to the liquid leakage sensor 160 detecting leaked coolant on the water receiving tray 150, it transmits the detected information to the main circuit board 140. The external heat dissipation module 100 may further include an alarm (not shown), electrically connected to the main circuit board 140, for issuing a liquid leakage warning.

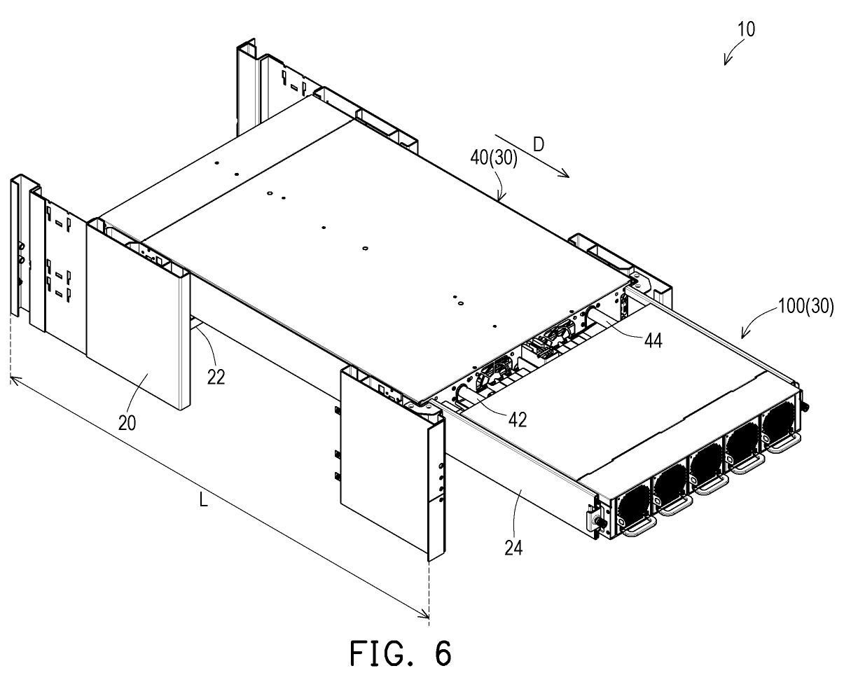

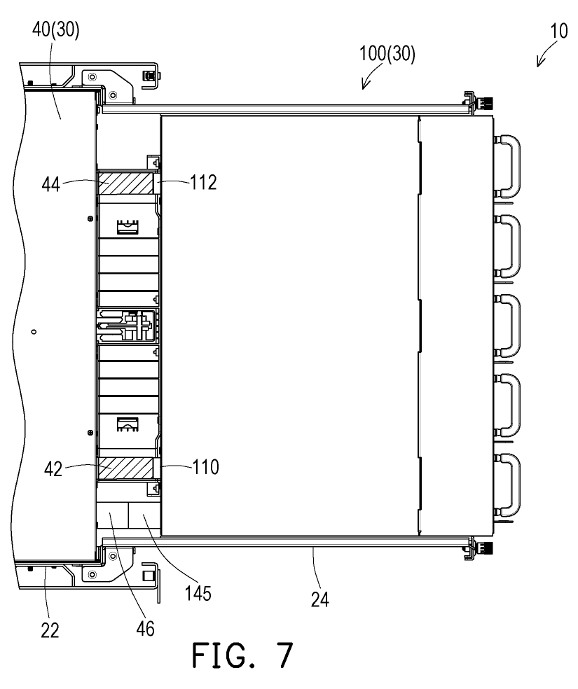

FIGS. 5 and 6 are schematic diagrams of different viewing angles of a server system according to an embodiment of the disclosure. FIG. 7 is a partially enlarged top view of FIG. 5. It is noted that only a portion of the cabinet 20 is shown in FIGS. 5 and 6 to more clearly illustrate the relationship among the server assembly 30, the rack shelf 22, and the extension support bracket 24.

Referring to FIGS. 5 - 7, the server system 10 of this embodiment includes a cabinet 20 and a server assembly 30. The server assembly 30 includes a server 40 and the aforementioned external heat dissipation module 100. The server 40 and the external heat dissipation module 100 are detachably disposed in the cabinet 20.

The cabinet 20 includes a rack shelf 22 and an extension support bracket 24 disposed on the rack shelf 22. The extension support bracket 24 partially overlaps the rack shelf 22 and extends from the rack shelf 22. The server 40 may be movably disposed on the rack shelf 22 and a portion of the extension support bracket 24 from the front side of the cabinet 20, and the external heat dissipation module 100 may be movably disposed on another portion of the extension support bracket 24 from the rear side of the cabinet 20.

In this embodiment, the cabinet 20 extends a greater depth by disposing the extension support bracket 24 on the rack shelf 22 to provide support for the external heat dissipation module 100. In addition, in this embodiment, the total length L of the rack shelf 22 and the extension support bracket 24 in a sliding direction D of the server 40 is less than or equal to 150 centimeters, which may comply with the depth specification of the cabinet 20.

As shown in FIG. 7, the server 40 includes a first fluid connector 42, a second fluid connector 44, and a server electrical connector 46 located on the same side. The external heat dissipation module 100 may be pluggably assembled to the server 40. Specifically, in response to the external heat dissipation module 100 being assembled to the server 40, the liquid inlet connector 110 of the external heat dissipation module 100 is docked with the first fluid connector 42 of the server 40, the liquid outlet connector 112 of the external heat dissipation module 100 is docked with the second fluid connector 44 of the server 40, and the module electrical connector 145 of the external heat dissipation module 100 is docked with the server electrical connector 46. In one embodiment, it is also possible that only the liquid inlet connector 110 of the external heat dissipation module 100 is docked with the first fluid connector 42 of the server 40, and the liquid outlet connector 112 of the external heat dissipation module 100 is docked with the second fluid connector 44 of the server 40. As shown in FIG. 5, the first fluid connector 42, the second fluid connector 44, the liquid inlet connector 110 and the liquid outlet connector 112 are located at the same plane.

In this embodiment, the server 40 and the external heat dissipation module 100 are directly docked and are located at the same plane during docking, without requiring connection of more pipelines as in the conventional full-panel cabinet 20 heat dissipation module. Thus, in addition to saving costs, the server assembly 30 of this embodiment may also shorten the distance and time for the coolant to flow through pipelines purely used for transportation, thereby improving heat dissipation performance.

In summary, the liquid inlet connector and the liquid outlet connector of the external heat dissipation module of the disclosure are exposed on the same side of the external heat dissipation module. In response to the external heat dissipation module being docked with the server, the liquid of the server may flow from the first fluid connector through the liquid inlet connector and the first pipeline of the external heat dissipation module to the liquid cooling radiator, and after being cooled by the liquid cooling radiator, flows from the second pipeline and the liquid outlet connector to the second fluid connector of the server, and returns to the server. That is, the external heat dissipation module of the disclosure may be directly externally connected to the server to dissipate heat for the server, improving heat dissipation efficiency and avoiding resource waste, and is not limited by the internal dimensions of the server.

What is claimed is:

1. An external heat dissipation module adapted to be connected to a server, comprising:
a chassis;
a liquid inlet connector exposed from the chassis;
a liquid outlet connector exposed from the chassis, wherein the liquid inlet connector and the liquid outlet connector are disposed on a same side of the chassis;
a liquid cooling radiator located inside the chassis;
a first pipeline located in the chassis and connected to the liquid inlet connector and the liquid cooling radiator; and
a second pipeline located in the chassis and connected to the liquid outlet connector and the liquid cooling radiator;
wherein liquid in the server is adapted for flowing from the liquid inlet connector to the liquid cooling radiator through the first pipeline, and after being cooled by the liquid cooling radiator, flowing back to the server from the liquid cooling radiator to the liquid outlet connector through the second pipeline.

2. The external heat dissipation module according to claim 1, further comprising:
a liquid tank located in the chassis, the liquid tank being configured to store the liquid after being cooled by the liquid cooling radiator; and
at least one pump located in the chassis and connected to the liquid tank, the pump being configured to drive the liquid cooled to flow.

3. The external heat dissipation module according to claim 2, wherein the second pipeline further comprises:
a first sub-pipe connecting the liquid cooling radiator and the liquid tank;
a second sub-pipe connecting the liquid tank and the pump; and
a third sub-pipe connecting the pump and the liquid outlet connector.

4. The external heat dissipation module according to claim 3, wherein the at least one pump comprises two pumps connected in parallel, and the two pumps are connected to the second sub-pipe and the third sub-pipe of the second pipeline, the two pumps operate alternately, or one of the pumps serves as a backup.

5. The external heat dissipation module according to claim 2, further comprising:
a fan assembly located in the chassis and blowing air toward the liquid cooling radiator to cool the liquid;
a main circuit board located in the chassis and electrically connected to the fan assembly and the at least one pump; and
a module electrical connector exposed from the chassis and electrically connected to the main circuit board, wherein the module electrical connector, the liquid inlet connector, and the liquid outlet connector are exposed on a same side of the external heat dissipation module.

6. The external heat dissipation module according to claim 5, wherein the fan assembly is electrically connected to the main circuit board through a fan circuit board.

7. The external heat dissipation module according to claim 5, wherein the module electrical connector is electrically connected to the main circuit board, and the module electrical connector is configured to obtain power from the server and transmit signals with the server.

8. The external heat dissipation module according to claim 1, further comprising:
a water receiving tray located below the liquid inlet connector and the liquid outlet connector.

9. The external heat dissipation module according to claim 8, wherein the water receiving tray is formed with arc-shaped.

10. The external heat dissipation module according to claim 8, wherein two sides of the water receiving tray is higher than a center.

11. The external heat dissipation module according to claim 8, wherein the water receiving tray further comprising a plurality of upright structural reinforcing ribs for increasing structural strength of the water receiving tray.

12. The external heat dissipation module according to claim 8, further comprising:
a liquid leakage sensor disposed on the water receiving tray and electrically connected to the main circuit board, the liquid leakage sensor being configured to sense whether the liquid is leaking.

13. A server assembly, comprising:
a server comprising a first fluid connector and a second fluid connector located on a same side; and
an external heat dissipation module according to claim 1, pluggably assembled to the server, wherein in response to the external heat dissipation module being assembled to the server, the liquid inlet connector is docked with the first fluid connector, the liquid outlet connector is docked with the second fluid connector, and the server and the external heat dissipation module are located at a same plane.

14. The server assembly according to claim 13, wherein the first fluid connector, the second fluid connector, the liquid inlet connector and the liquid outlet connector are located at a same plane.

15. A server system, comprising:
a cabinet;
a server detachably disposed in the cabinet and comprising a first fluid connector and a second fluid connector located on a same side; and
an external heat dissipation module according to claim 1, detachably disposed in the cabinet and pluggably assembled to the server, wherein in response to the external heat dissipation module being assembled to the server, the liquid inlet connector is docked with the first fluid connector, the liquid outlet connector is docked with the second fluid connector, and the server and the external heat dissipation module are located at a same plane.

16. The server system according to claim 15, wherein the cabinet comprises a rack shelf and an extension support bracket disposed on the rack shelf, the extension support bracket partially overlaps the rack shelf and extends from the rack shelf, and the server and the external heat dissipation module are movably disposed on the extension support bracket.

17. The server system according to claim 16, wherein a total length of the rack shelf and the extension support bracket in a sliding direction of the server is less than or equal to 150 centimeters.
